(19) United States
(12) Patent Application Publication
(10) Pub. No.: US 2026/0149265 A1
(43) Pub. Date: May 28, 2026

(54) CURRENT PROTECTION SYSTEM

(71) Applicant: Infineon Technologies AG, Neubiberg (DE)

(72) Inventors: Vincent THIERY, Aix En Provence (FR); Guillaume SILVE, Sartoux (FR)

(21) Appl. No.: 19/384,086

(22) Filed: Nov. 10, 2025

(30) Foreign Application Priority Data
Nov. 22, 2024 (DE) 102024134455.5

(51) Int. Cl. H02H 9/02; H03F 3/45

(52) U.S. Cl. CPC H02H 9/02; H03F 3/45076; H03F 2203/45212

(57) ABSTRACT

The invention relates to the field of current protection systems. The current protection system comprises a shunt sub-system, arranged between an input and an output of the current protection system, the shunt sub-system comprising a first switch and a shunt resistor, the first switch arranged in series with the shunt resistor. The current protection system further comprises a comparator sub-system, arranged in parallel to the shunt resistor, the comparator sub-system being configured for comparing a shunt voltage across the shunt resistor with a reference voltage, the comparator sub-system comprising an offset-compensated operational amplifier. And, the current protection system comprises a control component, arranged between an output of the comparator sub-system and a first control input of the first switch.

### TECHNICAL FIELD

The invention relates to the field of current protection systems. The invention further relates to a method for protecting a load from an overcurrent, to a system, and to a use.

### BACKGROUND

In at least some current protection systems, a shunt resistor is used for sensing a current of interest, e.g. a current through a switch. For current protection systems with small allowed maximum current and/or for shunt resistors with very low resistance, a shunt voltage across the shunt resistor may be very low. Measuring low shunt voltages with sufficient precision turned out to be a difficult task

### DESCRIPTION

One aspect relates to a current protection system comprising a shunt sub-system, which is arranged between an input and an output of the current protection system. The shunt sub-system comprises a first switch and a shunt resistor, the first switch is arranged in series with the shunt resistor. The current protection system further comprises a comparator sub-system, arranged in parallel to the shunt resistor, the comparator sub-system being configured for comparing a shunt voltage across the shunt resistor with a reference voltage. The comparator sub-system comprises an offset-compensated operational amplifier, and a control component, arranged between an output of the comparator sub-system and a first control input of the first switch.

The current protection system may be configured for protecting a switch and/or a load that may be controlled by the switch. The load may be arranged in series to the switch. The current protection system may be used for DC current, for AC current, and/or for currents of other wave forms. The current protection system comprises a shunt sub-system. The shunt sub-system is arranged between an input and an output of the current protection system. The shunt sub-system comprises a first switch and a shunt resistor, wherein the first switch is arranged in series with the shunt resistor. The first switch may, for instance, be a semiconductor and/or a relay. The resistance of the shunt resistor may depend on the maximum current that is to be protected by the current protection system. The shunt resistor may be an (ohmic) resistor, a Hall sensor, and/or another means that is able to sense a current of a line.

A comparator sub-system is arranged in parallel to the shunt resistor, wherein the comparator sub-system is configured for comparing a shunt voltage across the shunt resistor with a reference voltage. The comparator sub-system comprises an offset-compensated operational amplifier. Due to Ohm's law, the shunt voltage across the shunt resistor is proportional to a current through the shunt sub-system. For other types of shunt resistors, e.g. a Hall sensor, a similar dependency may apply. Thus, the comparator sub-system is configured for sensing a current through the shunt sub-system, i.e. through shunt resistor and the switch, possibly also through other components arranged in series to the shunt sub-system, e.g. through a load. Furthermore, a control component is arranged between an output of the comparator sub-system and a first control input of the first switch. The control input of the first switch may be a gate of an FET (Field-Effect Transistor), or a basis of a bipolar transistor.

Particularly by using the offset-compensated operational amplifier—i.e. by keeping the voltage offset of the operational amplifier (op-amp) low—, the current protection system is able to measure voltages, like the shunt voltage, very precisely, even in cases when low (shunt) voltages are to be measured. This high precision may be used for providing current protection even for small currents, and/or may be used for selecting small shunt resistances, with very low impact to the system to be protected and/or to the shunt resistor itself, e.g. by reducing the shunt resistor's heating at high system currents.

In various embodiments, the current protection system further comprises a second switch, the second switch being arranged in parallel to the shunt sub-system. The control component is arranged between the output of the comparator sub-system and a second control input of the second switch, so that the control component controls the input both of the first switch and of the second switch. The first switch and the second switch may be of the same type. The second switch may be designed for a higher current than the first switch. This arrangement may further reduce the current through the shunt resistor, because the current through the current protection system is split between the first switch and the second switch. Through the shunt sub-system flows a current that is proportional to the current through the second switch. Thus, the comparator sub-system is also configured for sensing a current through the second switch. These embodiments may allow to switch quite high currents, for example in some systems up to 10 A, in others up to 100 A, in others even up to 1000 A.

In various embodiments, the offset-compensated operational amplifier is designed as an auto-zero operational amplifier system. The auto-zero operational amplifier system provides an offset-compensation, specifically of high reliability.

In various embodiments, the auto-zero operational amplifier is designed as a ping-pong auto-zero operational amplifier system. The ping-pong auto-zero operational amplifier system comprises two essentially identical sub-circuits, whose switches are alternated on a regular basis. Detailed examples of ping-pong auto-zero operational amplifier systems are provided below.

In some embodiments, the auto-zero operational amplifier comprises a differential pair of semiconductors. A source of the first semiconductor is connected to the reference voltage, and a gate and a drain is connected to a reference current. A source of the second semiconductor is connected to the shunt voltage via a first phase switch, a gate of the second semiconductor is connected to the gate of the first semiconductor, and a drain of the second semiconductor is connected to a reference current. Furthermore, a first amplifier switch is arranged between the shunt voltage and the second semiconductor, a second amplifier switch is arranged between the source of the first semiconductor and the source of the second semiconductor. The auto-zero operational amplifier further comprises a third amplifier switch, whose first end is connected to the drain of the second semiconductor, a third semiconductor, whose gate is connected to a second end of the third amplifier switch, and a fourth semiconductor, whose gate is connected to the drain of the second semiconductor and to the drain of the third semiconductor. And, a first capacitor is arranged at the gate of the third semiconductor. The auto-zero operational amplifier further comprises a fourth amplifier switch, whose first end is connected to the drain of the fourth semiconductor, a fifth semiconductor, whose gate is connected to a second end of the third amplifier switch, and a fifth amplifier switch, whose first end is connected to the drain of the fourth semiconductor and to the drain of the fifth semiconductor, and whose second end is connected to an output of the auto-zero operational amplifier. And, a second capacitor is arranged at the gate of the fifth semiconductor. The semiconductors may be, e.g., FETs or bipolar transistors. One example embodiment of these embodiments is shown in FIG. 4. This embodiment may contribute to avoid issues of saturation of the op-amp during the offset compensation phase.

In various embodiments, the first switch and the second switch are a MOSFET (Metal Oxide Semiconductor Field-Effect Transistor), an NMOS, a PMOS, a bipolar semiconductor, an IGBT (Insulated-Gate Bipolar Transistor), or a relay, e.g. a reed relay.

In various embodiments, the shunt voltage that can be sensed by the comparator sub-system is less than 1 mV, for example less than 200 μV, for example less than or equal to 50 μV.

In various embodiments, the control component comprises a current-limiting controllable current-source. The controllable current-source is configured to be controlled by a semiconductor, which is arranged at an output of the comparator sub-system. By this, a current through the first switch and the second switch is limited, when the shunt voltage across the shunt resistor is higher than or equal to a first predefined reference voltage. One example embodiment of these embodiments is shown in FIG. 6a.

In various embodiments, the first predefined reference voltage has a hysteresis. This may be realized by an op-amp with hysteresis, e.g. by a Schmitt-trigger. These embodiments may be able to detect very fast, when an overcurrent situation is over. One example embodiment of these embodiments is shown in FIG. 7a.

In various embodiments, the control component comprises a latch, whose Set-input is configured to be set by an op-amp. So, the inverting output of the latch is configured to block the current through the first switch, when the shunt voltage across the shunt resistor is higher than or equal to a second predefined reference voltage. One example embodiment of these embodiments is shown in FIG. 5a.

In various embodiments, the control component comprises a switch arranged between the input and the output of the control component, wherein the switch is opened when the shunt voltage across the shunt resistor is higher than a second predefined reference voltage. By this, a tripping function of the current protection system can be realized. The tripping function May work additionally or as an alternative to a current limiting function.

In various embodiments, the control component consists of a wire, so that the first switch and the second switch opened when the shunt voltage across the shunt resistor is higher than a third predefined reference voltage. This may be a very simple implementation for realizing a tripping function, i.e. only a wire connects the output of the offset-compensated operational amplifier with control input of the first (and, if available the second) switch.

An aspect relates to a method for protecting a load from an overcurrent. The method comprises the steps of:
closing a first switch, the first switch being part of a shunt sub-system comprising the first switch and a shunt resistor, the first switch arranged in series with the shunt resistor, the shunt sub-system being arranged in series with the load;
sensing a shunt voltage across the shunt resistor;
comparing, by means of a comparator sub-system, the shunt voltage with a reference voltage, the comparator sub-system comprising an auto-zero operational amplifier; and
when the shunt voltage is higher than or equal to a first predefined reference voltage, limiting a current through the first switch.

In various embodiments, the method further comprises the steps of:
when the shunt voltage across the shunt resistor is higher than or equal to a second predefined reference voltage, opening the first switch.

In various embodiments, the method further comprises the steps of:
closing a second switch, the second switch, being arranged in parallel to the shunt sub-system; and
when the shunt voltage across the shunt resistor is higher than or equal to the first predefined reference voltage, limiting a current through the second switch.

In various embodiments, the method further comprises the steps of:
when the shunt voltage is higher than or equal to the second predefined reference voltage, opening the second switch.

An aspect relates to a system, which comprises a current protection system described above and/or below. The system further comprises a power generator, and it comprises at least one load, connected in series with the current protection system and the power generator. Examples of the power generator may comprise a battery, e.g. of a car, or a photovoltaic system. The load may be a single load of a plurality of loads, which may be connected in any topology. The load may be a “consumer” of any kind. In a car, the may be, e.g. a so-called “safety load” of a car, e.g. head light, engine control, breaking, or power steering.

An aspect relates to a use of a current protection system as described above and/or below in an automotive system, particularly for protecting the current protection system itself and/or consumers of a vehicle, a motor and/or a battery of an electric vehicle, a photovoltaic system and/or its consumer.

It should be noted that two or more embodiments described above and/or below can be combined, as far as technically feasible.

For further elucidation, the disclosure is described by means of embodiments shown in the figures. These embodiments are to be considered as examples only, but not as limiting.

### BRIEF DESCRIPTION OF THE DRAWINGS

The drawings depict:

FIGS. 1 and 2 schematically a system according to an embodiment;

FIG. 3 schematically an auto-zero operational amplifier as part of a comparator sub system according to an embodiment.

FIG. 4 a sub-circuit comprising one half (“ping”) of a complete auto-zero operational amplifier according to an embodiment.

FIG. 5a schematically a current protection system, which is an example for realizing a tripping function according to an embodiment.

FIG. 5b the timing behavior of the circuit in FIG. 5a according to an embodiment.

FIG. 6a schematically a current protection system 100, which is an example for realizing a current-limiting function according to an embodiment.

FIG. 6b the timing behavior of the circuit in FIG. 6a according to an embodiment.

FIG. 7a schematically a current protection system 100, which is another example for realizing a current-limiting function according to an embodiment.

FIG. 7b the timing behavior of the circuit in FIG. 7a according to an embodiment.

FIG. 8 a flow diagram according to an embodiment.

### DETAILED DESCRIPTION OF EMBODIMENTS

FIG. 1 shows schematically a system according to an embodiment. The system comprises a current protection system 100 and a load 300. The load 300 is connected to an output 190 of the current protection system 100. Additionally or as an alternative, the load 300 may be connected to an input 110 of the current protection system 100. The current protection system 100 comprises a shunt sub-system 120, arranged between the input 110 and the output 190 of the current protection system 100. The shunt sub-system 120 comprises a first switch M1 and a shunt resistor 140, the first switch M1 is arranged in series with the shunt resistor 140. The current protection system 100 further comprises a comparator sub-system 150, arranged in parallel to the shunt resistor 140. Terminals 151, 152 are arranged at the ends of the shunt resistor 140. The comparator sub-system 150 is configured for comparing a shunt voltage Uₛₕ across the shunt resistor 140 with a reference voltage U_{ref}. The comparator sub-system 150 comprises an offset-compensated operational amplifier 160. The current protection system 100 further comprises a control component 200, arranged between an output 180 of the comparator sub-system 150 and a first control input 121 (gate) of the first switch M1. Thus, the control component 200 controls the first switch M1, based on a comparison between the shunt voltage Uₛₕ and the reference voltage U_{ref}. The control component 200 may, e.g., realize a tripping and/or a current limiting function.

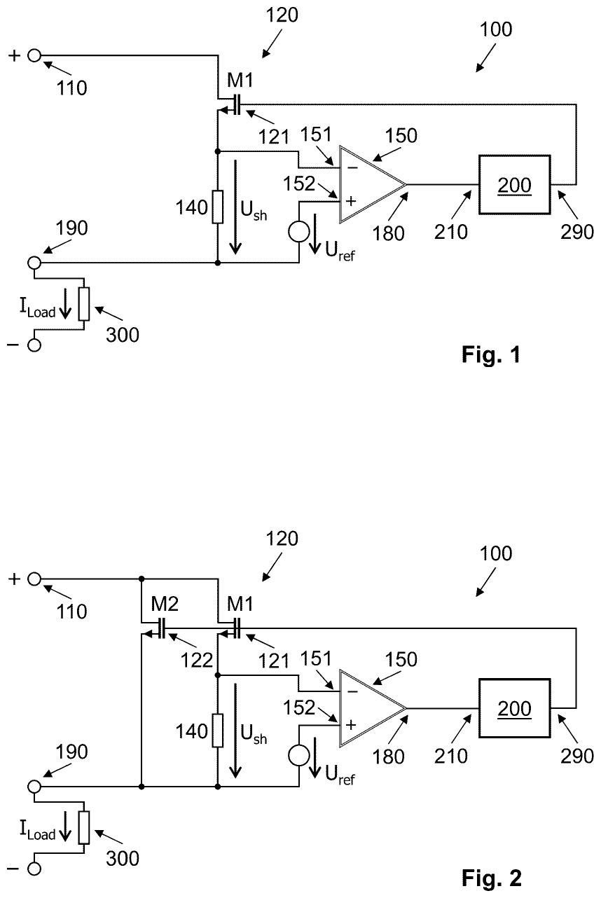

FIG. 2 show schematically a system according to an embodiment. The system of FIG. 2 is similar to the system of FIG. 1. Same reference signs designate same or similar components as in FIG. 1. FIG. 2 differs from FIG. 1 by an additional second switch M2, arranged in parallel to the shunt sub-system 120, wherein the control component 200 is arranged between the output 180 of the comparator sub-system 150 and a second control input 122 of the second switch M2. In numerous embodiments, the second switch M2 is designed for controlling a higher current than the first switch M1. In numerous embodiments, the second switch M2 is of the same or a quite similar type as the first switch M1, e.g. M1 and M2 are based on the same technology, and/or they may have same physical layers.

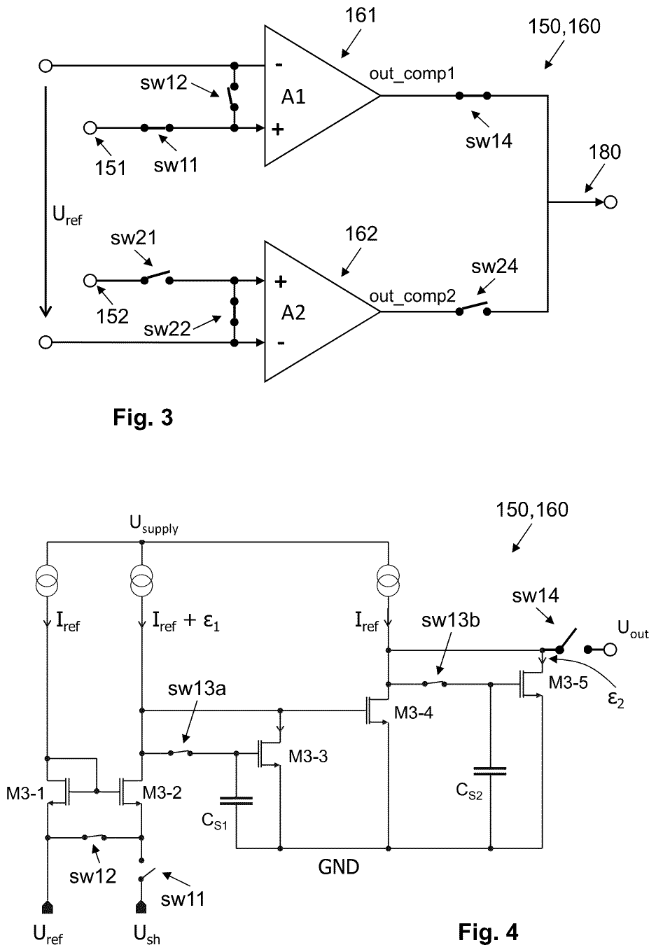

FIG. 3 shows schematically an auto-zero operational amplifier 160 as part of a comparator sub-system 150 according to an embodiment. The auto-zero operational amplifier 160 is arranged between terminal 151, 152 as inputs and terminal 180 as output (see FIGS. 1 and 2). The auto-zero operational amplifier 160 comprises two almost identical sub-circuits, each sub-circuit comprising an operational amplifier (op-amp), namely a first op-amp 161 and a second op-amp 162, respectively. The auto-zero operational amplifier 160 of this embodiment is realized as a so-called ping-pong auto-zero operational amplifier system.

The name “ping-pong” refers to a functional principle of this type of auto-zero operational amplifier system: In a phase #1, when the first op-amp 161 is amplifying signals, the second op-amp 162 is auto-zeroing. In a phase #2, it is the other way round, i.e. when the second op-amp 162 is amplifying signals, the first op-amp 161 is auto-zeroing The two amplifiers 161, 162 switch back and forth in phases #1 and #2, so the auto-zero operational amplifier 160 as a whole can work continuously; hence the name “ping-pong” auto-zero operational amplifier. FIG. 3 shows the auto-zero operational amplifier 160 in phase #1. The phases are switched by amplifier switches sw11 to sw14 and sw21 to sw24, using the scheme of Table 1. Note that switches sw13 and sw23 are not shown in FIG. 3. This is because said switches are located “inside” the op-amp 161 and 162, respectively. See FIG. 4 for an exemplary embodiment.

TABLE 1
Auto-zero Scheme

| Switch | Phase #1 | Phase #2 |
|---|---|---|
| sw11 | closed | open |
| sw12 | open | closed |
| sw13 | open | closed |
| sw14 | closed | open |
| sw21 | open | closed |
| sw22 | closed | open |
| sw23 | closed | open |
| sw24 | open | closed |

FIG. 4 shows, as a further embodiment of an auto-zero operational amplifier 160, a sub-circuit comprising one half (“ping”) of a complete auto-zero operational amplifier. As pointed out above, the other half (“pong”) is quite similar, due to the “ping-pong” functionality. The auto-zero operational amplifier 160 comprises a differential pair of semiconductors M3-1 and M3-2. The semiconductors M3-1 and M3-2 are arranged in a common gate configuration. The gate voltage of M3-2 is, thus, the same as the gate voltage of M3-1. The source-inputs of M3-1 and M3-2 are connected to the reference voltage U_{ref} and shunt voltage Uₛₕ (see FIGS. 1 and 2). M3-1 is in a diode configuration and in series with a reference current I_{ref}, thus generating a constant voltage across its drain-source path, since a constant current is injected into this path. When M3-1's source voltage increases or decreases, M3-1's gate voltage increases or decreases, respectively, by the same amount. Hence, when M3-2's source voltage is higher than the source voltage of M3-1, the gate-source voltage U_{GS} of M3-2 is lower than the U_{GS} of M3-1. Thus, less current flow through M3-2 than through M3-1. Consequently, M3-2's drain voltage is higher than M3-1's drain voltage (when using the same reference current in both branches). Accordingly, when the comparator is in auto-zero phase (sw12 closed, sw11 open), both source voltages are (essentially) equal, and both transistors (M3-1 and M3-2) have the same V_{GS}. As a result, M3-2's drain voltage should be equal to M3-1's one. Unfortunately, for real components, all the circuit imperfections or component tolerances usually lead to a small difference. This the offset that is compensated, e.g. by this embodiment. To this end, semiconductor M3-3 is connected to M3-2's drain. During the auto-zero phase, sw13 is closed, putting M3-3 also in diode configuration. As a consequence, when M3-2's drain voltage is higher than M3-3's threshold voltage (about 0.6 V), a current will flow through M3-3, the current being proportional to the magnitude of M3-2's drain voltage.

A further issue may arise, when M3-2 is more conductive than M3-1, due to the offset. Then, M3-2's drain voltage is lower than M3-3's threshold voltage, and no current is flowing, so no correction is possible. That is why the reference current on M3-2's branch is made greater than the one in M3-1's branch, so that independent of the voltage offset, the compensation circuit will be activated. In short, the input differential pair is voluntarily unbalanced (by having different biasing currents); by this, the compensation circuit can compensate for offset voltages that are either positive or negative. To ensure such unbalance between both reference currents, a current mirror structure is used, with differing dimensions for each branch. As a result, the output branch of the first stage is slightly overbiased, which is represented by the quantity &1.

Then, the compensation works as follows: M3-3 draws a current proportional to M3-2's drain voltage (which is an image of the voltage offset), in order to bring it back around M3-4's threshold voltage (cf. the IV characteristics of a diode). The first sampling capacitor C_{S1} is used to store this resulting voltage (M3-2 and M3-3 drain voltage) which is also M3-3's V_{GS}, i.e. the voltage controlling the current flowing through M3-3. Thus, once going to comparing phase (sw13 open), M3-3's Ves is held from auto-zero phase, allowing to compensate for the offset sensed during auto-zero phase, because the current flowing through M3-3 is the same in both phases. Due to this, an ability to store a precise voltage on C_{S1} may be relevant. The circuit described in previous paragraphs only details the first stage of this offset compensated amplifier. Indeed, this first stage lacks having sufficient gain to behave as a comparator. Thus, a complementary gain stage is added to the output of the first stage. This complementary gain stage is realized by amplifier M3-4, associated with a reference current I_{REF}.

However, for further improving the precision of this circuit, an analogue compensation mechanism used for the differential input pair is reciprocated on the second gain stage of the amplifier, with some adaptations. To have a “comparator” behavior, M3-4 needs to be either in blocking state or in passing state. Thus, at equilibrium—i.e. when sw12 and sw13 are closed, and sw11 is open—, both inputs are equal, so the output usually are in an equilibrium between its two states. Then, M3-4's V_{GS} is closed to its threshold voltage (about 0.6V). This is why, in first approximation, it is good to match M3-4 with M3-3, so they have equivalent threshold voltages, because M3-3 brings the first stage output voltage close to its own threshold voltage at equilibrium. But, to further improve the precision and to also compensate M3-4's voltage offset, a compensation circuit is added to the second stage of the amplifier, comprising M3-5, a second capacitor C_{S2} and switch sw13b. Since this is a single branch amplifying stage—not differential as the stage comprising M3-1 and M3-2—, a misbalance due to biasing currents cannot be created. Hence, M3-4's dimensions need to be chosen in a way to have a threshold voltage slightly bigger than M3-3's one so that, at equilibrium, M3-4 is rather blocking than passing. Then, M3-4's drain voltage should be higher than M3-5's threshold voltage (about 0.6V) during auto-zero phase, enabling the current to flow through it, thus actually compensating M3-4's offset. Thus, similarly to M3-3 for the first gain stage, M3-5 will bring the output voltage Uₒᵤₜ close to its own threshold voltage, while having a current proportional to M3-4's voltage offset flowing through it. Then, capacitor C_{S2} stores the voltage value that allows to reach the equilibrium at the output—when inputs are equal—, so, when going to comparing phase (sw13a and sw13b are open), a further compensating current ε₂ is maintained from auto-zero's phase, i.e. ε₂ is inserted between the drain of M3-5 and Vout.

To sum up the switches' states during each phase:
In phase #2 (“auto-zero” for this partial sub-circuit): Amplifier switches sw12, sw13a and sw13b are closed, while sw11 and sw14 are open.
In phase #1 (“comparison mode” for this partial sub-circuit): Amplifier switches sw11 and sw14 are closed, while sw12, sw13a and sw13b are open.

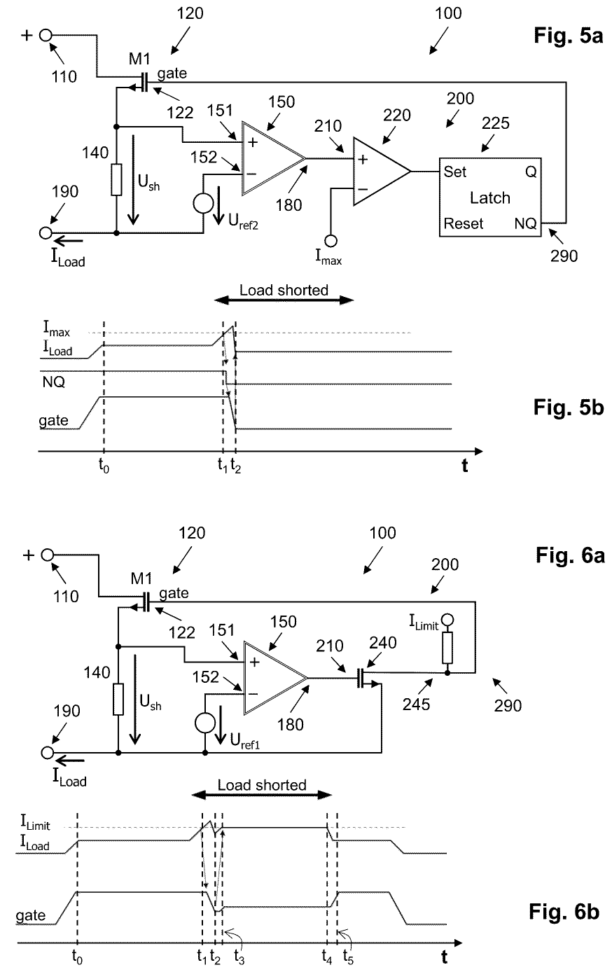

FIG. 5a shows schematically a current protection system 100, which is an example for realizing a tripping function according to an embodiment. The circuit of FIG. 5a is based on the circuit of FIG. 1. Same reference signs designate same or similar components as in FIG. 1. In FIG. 5a, the control component 200 comprises an op-amp 220 and a latch 225, with inputs Set and Reset, and outputs Q and NQ. FIG. 5b describes the timing behavior of the circuit in FIG. 5a: Firstly, the current protection system 100 is turned on, at t₀. As soon as a current I_{Load}>Iₘₐₓ is sensed, at t₁, by the comparator sub-system 150 (which compares Uₛₕ to U_{ref2}), the op-amp 220 activates the Set-input of latch 225, leading almost immediately to a signal change at the output NQ, i.e. output NQ switches from “1” to “0”. Output NQ is connected to the gate of switch M1, thus blocking (“tripping”) the current through M1. Note that the timing between t₁ and t₂ is spread, for better visibility of the effect of interest.

FIG. 6a shows schematically a current protection system 100, which is an example for realizing a current-limiting function according to an embodiment. The circuit of FIG. 6a is based on the circuit of FIG. 1. Same reference signs designate same or similar components as in FIG. 1. In FIG. 6a, the control component 200 comprises a semiconductor 240 and a resistor 245, which is configured for setting up the limiting current I_{Limit}. FIG. 6b describes the timing behavior of the circuit in FIG. 6a: Firstly, the current protection system 100 is turned on, at t₀. As soon as a current I_{Load}>I_{Limit} is sensed, at t₁, by the comparator sub-system 150 (which compares Uₛₕ to U_{ref1}), the semiconductor 240 is set or controlled by the resistor 245, and the current through M1 is reduced, at t₂. After a settling time, the current through M1 is limited to I_{Limit} at t₃. When the overcurrent ends, at t₄, the voltage at the gate is “restored” to its normal value, at t₅.

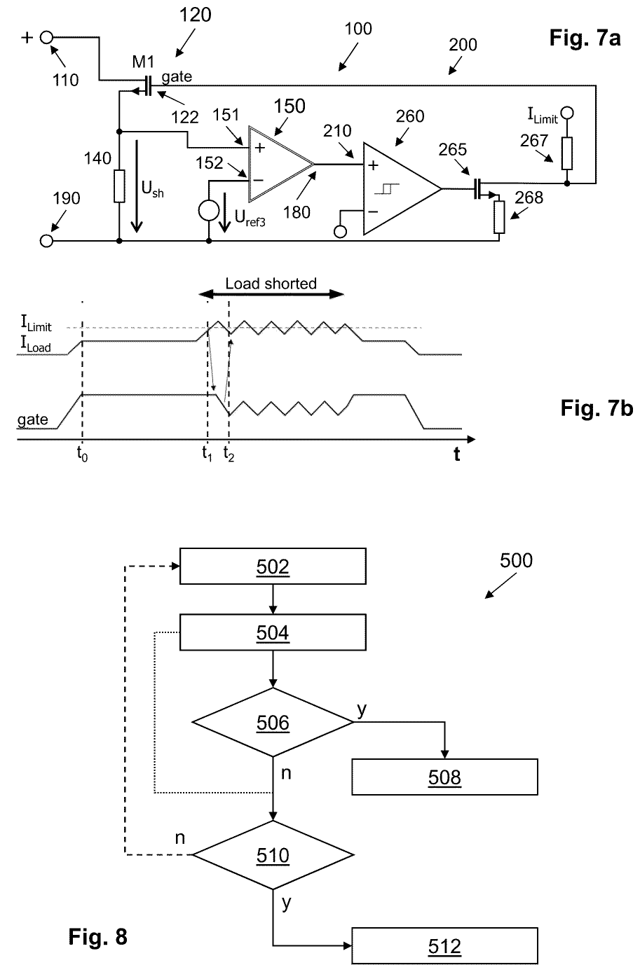

FIG. 7a shows schematically a current protection system 100, which is another example for realizing a current-limiting function according to an embodiment. The circuit of FIG. 7a is based on the circuit of FIG. 1. Same reference signs designate same or similar components as in FIG. 1. In FIG. 7a, the control component 200 comprises an op-amp 260 with a hysteresis, e.g. a so-called Schmitt-trigger. The op-amp 260 controls a semiconductor 265. A resistor 267 is configured for setting up the limiting current I_{Limit}. A further resistor 268 may be arranged between a source of the semiconductor 265 and the output 190. As soon as a current I_{Load}>I_{Limit} is sensed, at t₁, by the comparator sub-system 150 (which compares Uₛₕ to U_{ref1}), the semiconductor 265 controls M1 to block the current through M1. At t₂, I_{Load} is below I_{Limit} again, so that M1 is opened again. When the overcurrent still exists, M1 is blocked again, and so on. This continues, until the (reason for the) overcurrent vanishes.

FIG. 8 shows a flow diagram 500 of method for protecting a load from an overcurrent, according to an embodiment. In a step 502, a first switch M1 (see FIG. 1) is closed. The first switch M1 is part of a shunt sub-system 120, which comprises the first switch M1 and a shunt resistor 140. The first switch M1 is arranged in series with the shunt resistor 140. The shunt sub-system 120 is arranged in series with the load 300. In a step 504, a shunt voltage Uₛₕ across the shunt resistor 140 is sensed. In a step 506, the shunt voltage Uₛₕ is compared, by means of a comparator sub-system 150, with a reference voltage U_{ref}. The comparator sub-system 150 comprises an offset-compensated operational amplifier 160. When the shunt voltage Uₛₕ is higher than or equal to a first predefined reference voltage U_{ref1}, in a step 508, a current through the first switch M1 is limited.

Additionally, or—depicted by a dotted line in FIG. 8—as an alternative, in a step 510 it is check, if the shunt voltage Uₛₕ across the shunt resistor 140 is higher than or equal to a second predefined reference voltage U_{ref2}. If, yes, in a step 512, the first switch M1 is opened. Note that the first predefined reference voltage U_{ref1} can be the same or a different voltage than U_{ref2}.

A further aspect relates to some examples.
Example 1 relates to a current protection system comprising a shunt sub-system, arranged between an input and an output of the current protection system, the shunt sub-system comprising a first switch and a shunt resistor, the first switch arranged in series with the shunt resistor; a comparator sub-system, arranged in parallel to the shunt resistor, the comparator sub-system being configured for comparing a shunt voltage across the shunt resistor with a reference voltage, the comparator sub-system comprising an offset-compensated operational amplifier; and a control component, arranged between an output of the comparator sub-system and a first control input of the first switch.
Example 2 relates to the current protection system of example 1, further comprising a second switch, the second switch, arranged in parallel to the shunt sub-system, wherein the control component is arranged between the output of the comparator sub-system and a second control input of the second switch.
Example 3 relates to the current protection system of examples 1 or 2, wherein offset-compensated operational amplifier is designed as an auto-zero operational amplifier system.
Example 4 relates to the current protection system of examples 1 or 2, wherein the auto-zero operational amplifier is designed as a ping-pong auto-zero operational amplifier system.
Example 5 relates to the current protection system of examples 1 or 2, wherein the auto-zero operational amplifier comprises: a differential pair of semiconductors, wherein a source of the first semiconductor is connected to the reference voltage, and a gate and a drain connected to a reference current, a source of the second semiconductor is connected to the shunt voltage via a first phase switch, a gate connected to the gate of the first semiconductor, and a drain connected to a reference current, a first amplifier switch, arranged between the shunt voltage and the second semiconductor, a second amplifier switch, arranged between the source of the first semiconductor and the source of the second semiconductor; a third amplifier switch, whose first end is connected to the drain of the second semiconductor; a third semiconductor, whose gate is connected to a second end of the third amplifier switch; a first capacitor, arranged at the gate of the third semiconductor; a fourth semiconductor, whose gate is connected to the drain of the second semiconductor and to the drain of the third semiconductor: a fourth amplifier switch, whose first end is connected to the drain of the fourth semiconductor; a fifth semiconductor, whose gate is connected to a second end of the third amplifier switch; and a second capacitor, arranged at the gate of the fifth semiconductor; a fifth amplifier switch, whose first end is connected to the drain of the fourth semiconductor and to the drain of the fifth semiconductor, and whose second end is connected to an output of the auto-zero operational amplifier.
Example 6 relates to the current protection system of any one of the preceding examples, wherein the first switch and the second switch are a MOSFET, an NMOS, a PMOS, a bipolar semiconductor, an IGBT switch, or a relay.
Example 7 relates to the current protection system of any one of the preceding examples, wherein the shunt voltage that can be sensed by the comparator sub-system is less than 1 mV, for example less than 200 μV, for example less than 50 μV.
Example 8 relates to the current protection system of any one of the preceding examples, wherein the control component comprises a current-limiting controllable current-source, the controllable current-source being configured to be controlled by a semiconductor, which is arranged at an output of the comparator sub-system, thus limiting a current through the first switch and the second switch when the shunt voltage across the shunt resistor is higher than or equal to a first predefined reference voltage.
Example 9 relates to the current protection system of example 8, wherein the first predefined reference voltage has a hysteresis.
Example 10 relates to the current protection system of any one of the examples 1 to 7, wherein the control component comprises a latch, whose Set-input is configured to be set by an op-amp, so that the inverting output of the latch is configured to block the current through the first switch, when the shunt voltage across the shunt resistor is higher than or equal to a second predefined reference voltage.
Example 11 relates to the current protection system of any one of the examples 1 to 7, wherein the control component comprises a switch arranged between the input and the output of the control component, wherein the switch is opened when the shunt voltage across the shunt resistor is higher than a second predefined reference voltage.
Example 12 relates to the current protection system of any one of the examples 1 to 7, wherein the control component consists of a wire, so that the first switch and the second switch opened when the shunt voltage across the shunt resistor is higher than a third predefined reference voltage.
Example 13 relates to a method for protecting a load from an overcurrent, the method comprising the steps of: closing a first switch, the first switch being part of a shunt sub-system comprising the first switch and a shunt resistor, the first switch arranged in series with the shunt resistor, the shunt sub-system being arranged in series with the load; sensing a shunt voltage across the shunt resistor; comparing, by means of a comparator sub-system, the shunt voltage with a reference voltage, the comparator sub-system comprising an offset-compensated operational amplifier; and when the shunt voltage is higher than or equal to a first predefined reference voltage, limiting a current through the first switch.
Example 14 relates to the method of example 13, further comprising the steps of: when the shunt voltage across the shunt resistor is higher than or equal to a second predefined reference voltage, opening the first switch.
Example 15 relates to the method of example 13 or 14, further comprising the steps of: closing a second switch, the second switch, being arranged in parallel to the shunt sub-system; and when the shunt voltage across the shunt resistor is higher than or equal to the first predefined reference voltage, limiting a current through the second switch.
Example 16 relates to the method of example 13, 14 or 15, further comprising the steps of: when the shunt voltage is higher than or equal to the second predefined reference voltage, opening the second switch.
Example 17 relates to a system comprising: a current protection system according to any one of the examples 1 to 12; a power generator; and at least one load, connected in series with the current protection system and the power generator.
Example 18 relates to a use of a current protection system according to any one of the examples 1 to 12 in an automotive system, particularly for protecting the current protection system itself and/or consumers of a vehicle, a motor and/or a battery of an electric vehicle, a photovoltaic system and/or its consumer.

1. A current protection system comprising:
a shunt sub-system, arranged between an input and an output of the current protection system,
the shunt sub-system comprising a first switch (M1) and a shunt resistor, the first switch (M1) arranged in series with the shunt resistor;
a comparator sub-system, arranged in parallel to the shunt resistor, the comparator sub-system being configured for comparing a shunt voltage (Uₛₕ) across the shunt resistor with a reference voltage (U_{ref}), the comparator sub-system comprising an offset-compensated operational amplifier; and
a control component, arranged between an output of the comparator sub-system and a first control input of the first switch (M1).

2. The current protection system of claim 1, further comprising a second switch (M2),
the second switch (M2), arranged in parallel to the shunt sub-system, wherein the control component is arranged between the output of the comparator sub-system and a second control input of the second switch (M2).

3. The current protection system of claim 1,
wherein offset-compensated operational amplifier is designed as an auto-zero operational amplifier system.

4. The current protection system of claim 1,
wherein the auto-zero operational amplifier is designed as a ping-pong auto-zero operational amplifier system.

5. The current protection system of claim 1,
wherein the auto-zero operational amplifier comprises:
a differential pair of semiconductors (M3-1, M3-2),
wherein a source of the first semiconductor (M3-1) is connected to the reference voltage (U_{ref}), and a gate and a drain connected to a reference current, a source of the second semiconductor (M3-2) is connected to the shunt voltage (Uₛₕ) via a first phase switch (sw11), a gate connected to the gate of the first semiconductor (M3-2), and a drain connected to a reference current,
a first amplifier switch (sw11), arranged between the shunt voltage (Uₛₕ) and the second semiconductor (M3-2),
a second amplifier switch (sw11), arranged between the source of the first semiconductor (M3-1) and the source of the second semiconductor (M3-2);
a third amplifier switch (sw13a), whose first end is connected to the drain of the second semiconductor (M3-2);
a third semiconductor (M3-3), whose gate is connected to a second end of the third amplifier switch (sw13a);
a first capacitor (C_{S1}), arranged at the gate of the third semiconductor (M3-3);
a fourth semiconductor (M3-4), whose gate is connected to the drain of the second semiconductor (M3-2) and to the drain of the third semiconductor (M3-3):
a fourth amplifier switch (sw13b), whose first end is connected to the drain of the fourth semiconductor (M3-4);
a fifth semiconductor (M3-5), whose gate is connected to a second end of the third amplifier switch (sw13b); and
a second capacitor (C_{S2}), arranged at the gate of the fifth semiconductor (M3-5);
a fifth amplifier switch (sw14), whose first end is connected to the drain of the fourth semiconductor (M3-4) and to the drain of the fifth semiconductor (M3-5), and whose second end is connected to an output (Uₒᵤₜ) of the auto-zero operational amplifier.

6. The current protection system of claim 5,
wherein the first switch (M1) and the second switch (M2) are a MOSFET, an NMOS, a PMOS, a bipolar semiconductor, an IGBT switch, or a relay.

7. The current protection system of claim 1,
wherein the shunt voltage (Uₛₕ) that can be sensed by the comparator sub-system is less than 1 mV, for example less than 200 μV, for example less than 50 μV.

8. The current protection system of claim 1,
wherein the control component comprises a current-limiting controllable current-source, the controllable current-source being configured to be controlled by a semiconductor, which is arranged at an output of the comparator sub-system,
thus limiting a current through the first switch (M1) and the second switch (M2) when the shunt voltage (Uₛₕ) across the shunt resistor is higher than or equal to a first predefined reference voltage (U_{ref1}).

9. The current protection system of claim 8,
wherein the first predefined reference voltage (U_{ref1}) has a hysteresis.

10. The current protection system of claim 1,
wherein the control component comprises a latch, whose Set-input is configured to be set by an op-amp,
so that the inverting output (NQ) of the latch is configured to block the current through the first switch (M1), when the shunt voltage (Uₛₕ) across the shunt resistor is higher than or equal to a second predefined reference voltage (U_{ref2}).

11. The current protection system of claim 1,
wherein the control component comprises a switch arranged between the input (210) and the output (290) of the control component, wherein the switch is opened when the shunt voltage (Uₛₕ) across the shunt resistor is higher than a second predefined reference voltage (U_{ref2}).

12. The current protection system of claim 1,
wherein the control component consists of a wire, so that the first switch (M1) and the second switch (M2) opened when the shunt voltage (Uₛₕ) across the shunt resistor is higher than a third predefined reference voltage (U_{ref3}).

13. A method for protecting a load from an overcurrent, the method comprising the steps of:
closing a first switch (M1), the first switch (M1) being part of a shunt sub-system comprising the first switch (M1) and a shunt resistor, the first switch (M1) arranged in series with the shunt resistor, the shunt sub-system being arranged in series with the load;
sensing a shunt voltage (Uₛₕ) across the shunt resistor;
comparing, by means of a comparator sub-system, the shunt voltage (Uₛₕ) with a reference voltage (U_{ref}), the comparator sub-system comprising an offset-compensated operational amplifier; and
when the shunt voltage (Uₛₕ) is higher than or equal to a first predefined reference voltage (U_{ref1}), limiting a current through the first switch (M1).

14. The method of claim 13, further comprising the steps of:
when the shunt voltage (Uₛₕ) across the shunt resistor is higher than or equal to a second predefined reference voltage (U_{ref2}), opening the first switch (M1).

15. The method of claim 13, further comprising the steps of:
closing a second switch (M2), the second switch (M2), being arranged in parallel to the shunt sub-system; and
when the shunt voltage (Uₛₕ) across the shunt resistor is higher than or equal to the first predefined reference voltage (U_{ref1}), limiting a current through the second switch (M2).

16. The method of claim 13, further comprising the steps of:
when the shunt voltage (Uₛₕ) is higher than or equal to the second predefined reference voltage (U_{ref2}), opening the second switch (M2).

17. A system comprising:
a current protection system, comprising:
a shunt sub-system, arranged between an input and an output of the current protection system,
the shunt sub-system comprising a first switch (M1) and a shunt resistor, the first switch (M1) arranged in series with the shunt resistor;
a comparator sub-system, arranged in parallel to the shunt resistor,
the comparator sub-system being configured for comparing a shunt voltage (Uₛₕ) across the shunt resistor with a reference voltage (U_{ref}), the comparator sub-system comprising an offset-compensated operational amplifier; and
a control component, arranged between an output of the comparator sub-system and a first control input of the first switch (M1);
a power generator; and
at least one load, connected in series with the current protection system and the power generator.
